(19) United States
(12) Patent Application Publication
(10) Pub. No.: US 2012/0250272 A1
(43) Pub. Date: Oct. 4, 2012

(54) PROTECTIVE CASING AND WATERPROOF COVER THEREOF

(76) Inventor: Kai-Hung Wang, Kaohsiung City (TW)

(21) Appl. No.: 13/075,083

(22) Filed: Mar. 29, 2011

(51) Int. Cl. H05K 5/03

(52) U.S. Cl. 361/752

(57) ABSTRACT

A waterproof cover is implemented in a protective casing for an electronic device. An opening is formed on the protective casing at a position corresponding to a connecting terminal of a circuit board inside the protective casing, and an engaging structure is formed on the protective casing at a side of the opening. The waterproof cover includes a covering portion having a protrusion, an engaging portion and a flexible connecting portion. The protrusion plugs into the opening when the covering portion covers the opening. The engaging portion is used for detachably engaging the engaging structure. The flexible connecting portion connects the covering portion and the engaging portion for making the covering portion bendable relative to the engaging portion.

### BACKGROUND OF THE INVENTION

1. Field of the Invention

The present invention relates to a protective casing and a waterproof cover thereof, and more particularly, to a waterproof cover that is partially connected to the protective casing.

2. Description of the Prior Art

As technology advances, various electronic devices including mobile phone, media player (e.g. MP3 player), personal digital assistant (PDA) and so on have been developed to make life more convenient and colorful. In order to protect an electronic device from harm, a user may use a protective casing to accommodate the electronic device. Generally, there are usually openings formed on the protective casing for connectors or audio jacks to be inserted into. Especially for waterproof, rugged protective casings, a waterproof cover for each opening of the protective casing is required for preventing the internal connecting terminal from damage. The conventional waterproof cover is usually fixed on the protective casing through one or more screws. The screwing technique not only increases the labor cost, but also make it more complicated to assemble the protective casing.

### SUMMARY OF THE INVENTION

The present invention provides a waterproof cover implemented in a protective casing for an electronic device. An opening is formed on the protective casing at a position corresponding to a connecting terminal of a circuit board inside the protective casing, and an engaging structure is formed on the protective casing at a side of the opening. The waterproof cover includes a covering portion having a protrusion, an engaging portion and a flexible connecting portion. The protrusion is used for plugging into the opening when the covering portion covers the opening, and the engaging portion is used for detachably engaging with the engaging structure. The flexible connecting portion connects the covering portion and the engaging portion for making the covering portion bendable relative to the engaging portion.

The present invention further provides a protective casing for an electronic device. The protective casing includes a main casing and at least one waterproof cover. The main casing includes a circuit board and an engaging structure. The circuit board is disposed inside the main casing and having a connecting terminal. An opening is formed on the main casing at a position corresponding to the connecting terminal. The engaging structure is formed at a side of the opening. The waterproof cover disposed on the main casing includes a covering portion having a protrusion, an engaging portion and a flexible connecting portion. The protrusion is used for plugging into the opening when the covering portion covers the opening, and the engaging portion is used for detachably engaging with the engaging structure. A flexible connecting portion connects the covering portion and the engaging portion for making the covering portion bendable relative to the engaging portion.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view of a protective casing operated at a closed state according to a preferred embodiment of the invention.

FIG. 2 is a perspective view of the protective casing in FIG. 1 from another view angle.

FIG. 3 is a perspective view of the protective casing in FIG. 1 operated at an opened state.

FIG. 4 is an exploded view of a lower casing in FIG. 3.

FIG. 5 is an exploded diagram of a waterproof cover and a main casing in FIG. 1

FIG. 6 is a perspective view illustrating an electronic device accommodated in a first accommodating space.

FIG. 7 is an enlarged diagram of the waterproof cover in FIG. 5 from another view angle.

### DETAILED DESCRIPTION

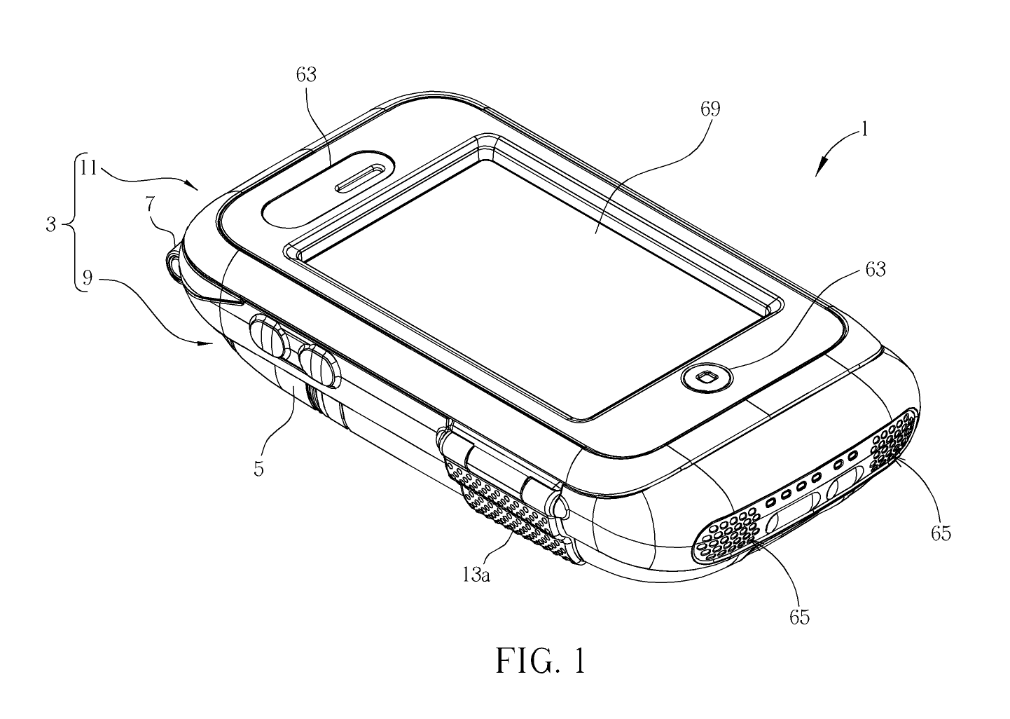

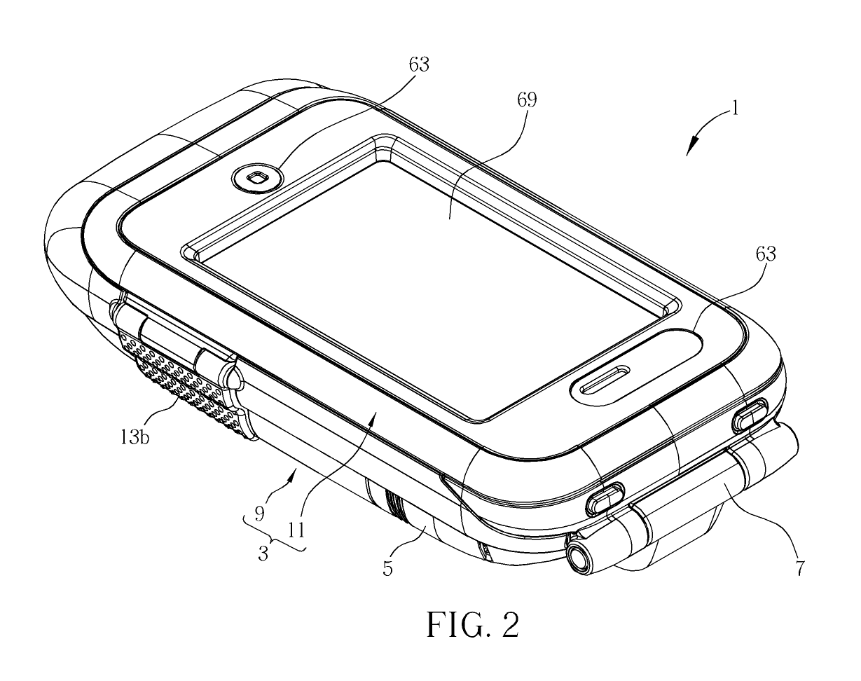

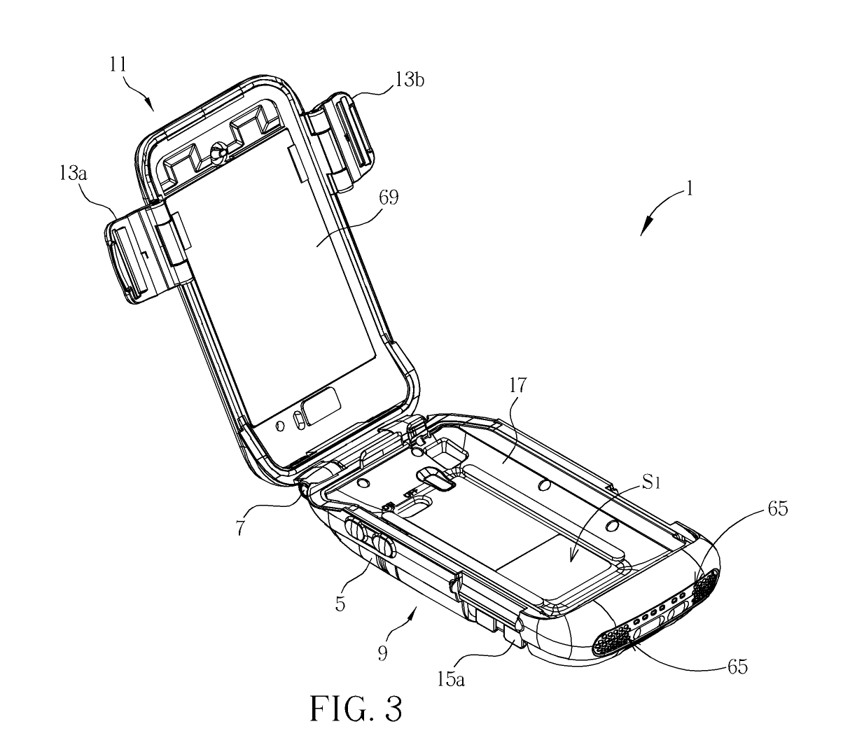

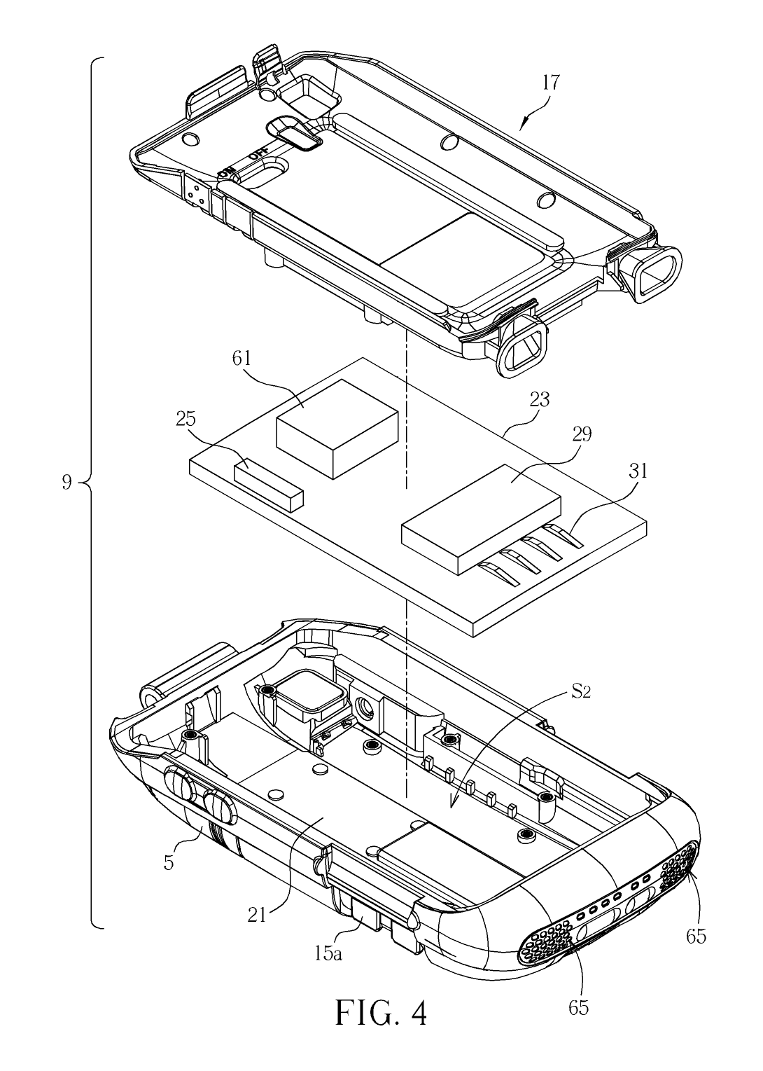

Please refer to FIGS. 1 to 4. FIG. 1 is a perspective view of a protective casing 1 operated at a closed state according to a preferred embodiment of the invention. FIG. 2 is a perspective view of the protective casing 1 in FIG. 1 from another view angle. FIG. 3 is a perspective view of the protective casing 1 in FIG. 1 operated at an opened state. FIG. 4 is an exploded view of a lower casing 9 in FIG. 3.

As shown in FIGS. 1 to 3, the protective casing 1 includes a main casing 3, at least one waterproof cover 5 and a hinge assembly 7. As shown in FIG. 1 and FIG. 2, in this embodiment, there are two waterproof covers 5 respectively disposed at opposite sides of the main casing 3 (but not limited thereto). The main casing 3 includes the lower casing 9 and an upper casing 11, and the hinge assembly 7 is used for pivotally connecting the upper casing 11 and the lower casing 9. Furthermore, the upper casing 11 may include two fastener members 13a, 13b pivotally connected to opposite sides of the upper casing 11, the lower casing 9 may include two fastener structures 15a, 15b formed on opposite sides of the lower casing 9, and the two fastener members 13a, 13b can be detachably fastened with the two fastener structures 15a, 15b respectively. It should be noted that there is only one fastener structure 15a shown in FIG. 3 due to the view angle. When the protective casing 1 is in the closed state shown in FIGS. 1 and 2, the two fastener members 13a, 13b are fastened with the two fastener structures 15a, 15b respectively. On the other hand, when the protective casing 1 is in the opened state shown in FIG. 3, the two fastener members 13a, 13b are detached from the two fastener structures 15a, 15b respectively and the upper casing 11 is free to rotate with respect to the lower casing 9 via the hinge assembly 7. Accordingly, a user can operate the protective casing 1 between the closed state and the opened state.

As shown in FIG. 3 and FIG. 4, the lower casing 9 may further include a partition member 17, and the upper casing 11 cooperates with the lower casing 9 to form the first accommodating space S₁ therebetween, wherein the first accommodating space S₁ is above the partition member 17. As shown in FIG. 4, a second accommodating space S₂ is between the partition member 17 and a bottom 21 of the lower casing 9. In this embodiment, the protective casing 1 may further include a circuit board 23 disposed in the second accommodating space S₂ and the circuit board 23 has a connecting terminal 25.

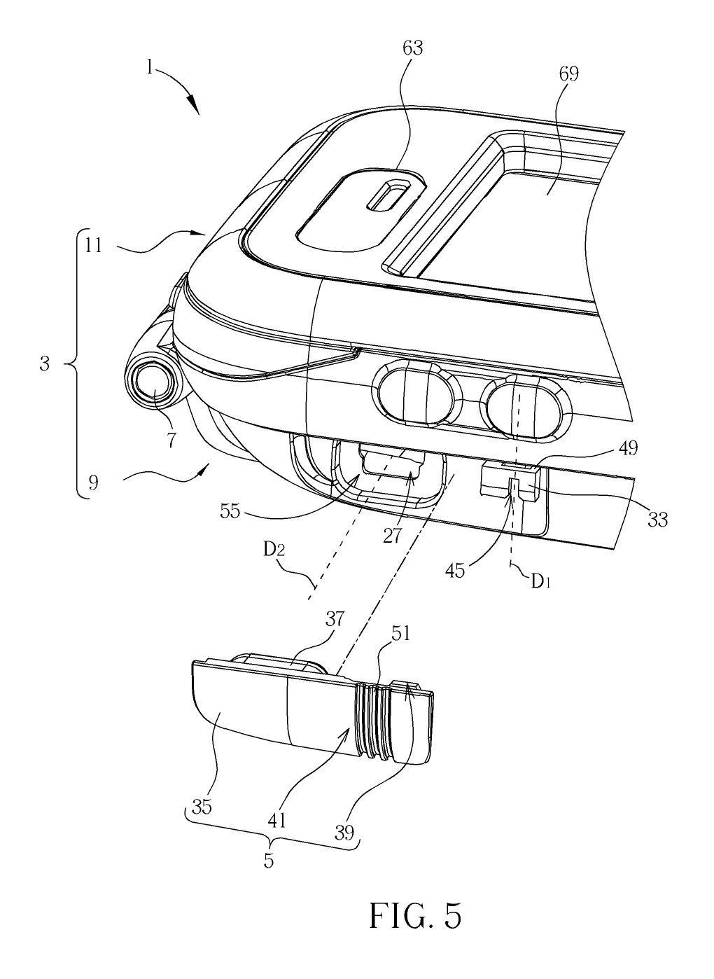

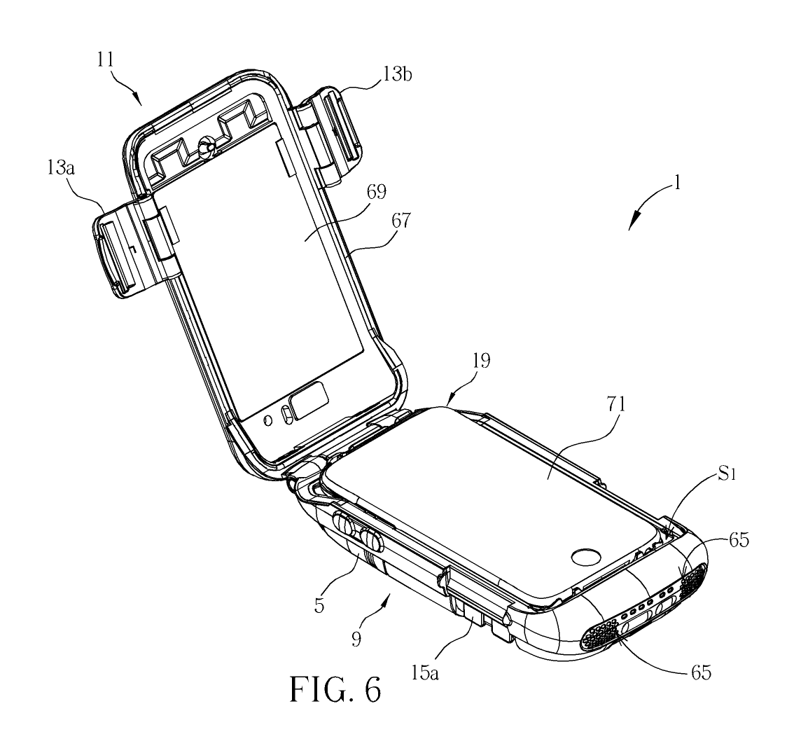

Please refer to FIG. 5 and FIG. 6. FIG. 5 is an exploded diagram of the waterproof cover 5 and the main casing 3 in FIG. 1, and FIG. is a perspective view illustrating an electronic device 19 accommodated in the first accommodating space S₁. In this embodiment, the electronic device 19 is preferably, but not limited to, a mobile phone. It can also be a media player (e.g. MP3 player), a personal digital assistant (PDA) and so on.

As shown in FIG. 5 and FIG. 6, an opening 27 is formed on the main casing 3 at a position corresponding to the connecting terminal 25 of the circuit board 23 inside the protective casing 1. In other words, after the circuit board 23 is installed in the second accommodating space S₂, the connecting terminal 25 of the circuit board 23 is aimed at the opening 27 for allowing an external connector of an external electronic device (not shown) to be connected to the connecting terminal 25 via the opening 27. In this embodiment, the connecting terminal 25 is preferably a USB (Universal Serial Bus) port and the external connector is preferably a USB plug compatible with the connecting terminal 25.

In addition, the circuit board 23 further includes a power supply unit 29 and a connector 31, and the power supply unit 29 is electrically connected to the connecting terminal 25 and the connector 31. Furthermore, when the electronic device 19 is accommodated in the first accommodating space S₁ (as shown in FIG. 6), a connector (not shown) of the electronic device 19 is electrically connected to the connector 31 of the circuit board 23, such that the power supply unit 29 can supply power to the electronic device 19. Furthermore, data from the electronic device 19 can be transferred to an external connector of an external electronic device (e.g. a PC, a PDA and so on) via the circuit board 23 by using the connector 31 and the connecting terminal 25. In practical applications, the power supply unit 29 is preferably a battery.

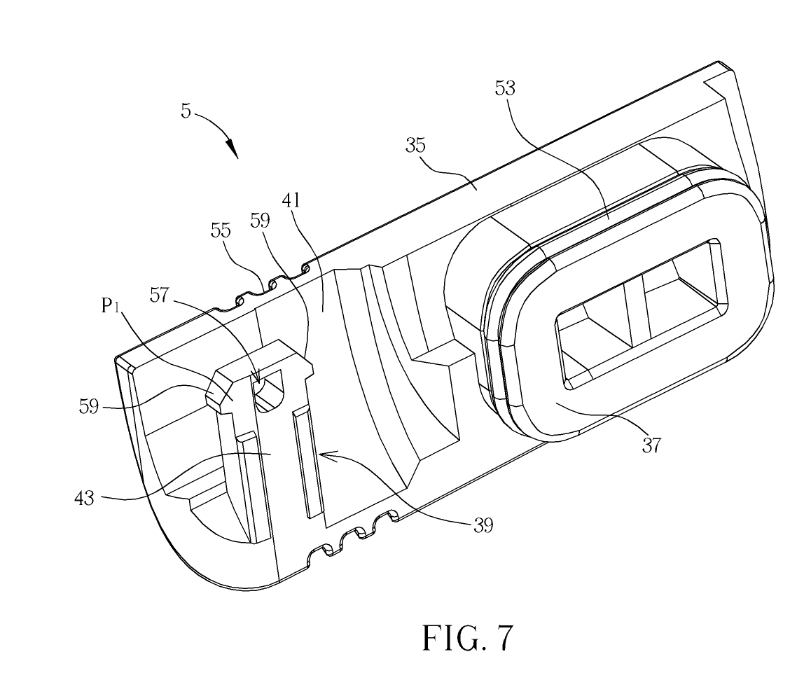

More detailed description for the structural design of the waterproof cover 5 is provided as follows. Please refer to FIG. 5 and FIG. 7. FIG. 7 is an enlarged diagram of the waterproof cover 5 in FIG. 5 from another view angle. As shown in FIG. 5 and FIG. 7, an engaging structure 33 is formed at a side of the opening 27. The waterproof cover 5 includes a covering portion 35 having a protrusion 37, an engaging portion 39 and a flexible connecting portion 41. The engaging portion 39 is used for detachably engaging with the engaging structure 33. Furthermore, the engaging portion 39 has a hook member 43 and the engaging structure 33 has a corresponding guide slot 45 formed therein for allowing the hook member 43 to pass through. After the hook member 43 passes through the guide slot 45, a hook end P₁ hook member 43 fastens an edge 49 of the engaging structure 33 for fixing the engaging portion 39 to the engaging structure 33. In this embodiment, the hook end P₁ is substantially, but not limited to, T-shaped with two hook structures protruding from both sides of the hook end P₁ (as shown in FIG. 7). In other embodiments, the hook end P₁ can be a hook-shaped with only one hook structure protruding from one side of the hook end P₁.

The flexible connecting portion 41 connects the covering portion 35 and the engaging portion 39 for making the covering portion 35 bendable relative to the engaging portion 39. In practical application, the flexible connecting portion 41 can further include a plurality of groove structures 51 so as to make the flexible connecting portion 41 more flexible and enhance durability of the flexible connecting portion 41, and the flexible connecting portion 41 can be integrally formed with the covering portion 35 and the engaging portion 39. Furthermore, the waterproof cover 5 can include a first sealing member 53 disposed on an outer side of the protrusion 37 for forming a waterproof sealing between the covering portion 35 and the inner surface of the opening 27. The first sealing member 53 can be exemplified by an O-ring. The protrusion 37 plugs into the opening 27 when the covering portion 35 covers the opening 27.

In the following, more detailed description for the assembly and disassembly of the waterproof cover 5 and the lower casing 9 is provided. Please refer to FIG. 5, FIG. 6 and FIG. 7 again. First, the hook end P₁ of the engaging portion 39 of the waterproof cover 5 is inserted into the guide slot 45 of the engaging structure 33 along an engaging direction D₁ as shown in FIG. 5, which is substantially perpendicular to an upright direction D₂ of the opening 27. Next, the protrusion 37 of the covering portion 35 is plugged in a recess 55 along the upright direction D₂ for sealing the opening 27 cooperatively with the first sealing member 53, so as to complete the assembly of the waterproof cover 5 and the lower casing 9. As shown in FIG. 7, there is a hole 57 formed in the hook end P₁ to facilitate the deformation of the hook end P₁, and at least one chamfer 59 (two shown in FIG. 7) is formed at the hook end P₁ of the hook member 43, so as to help the hook end P₁ passes through the guide slot 45 more easily.

On the other hand, if the user wants to use the connecting terminal 25, for example plugging an earphone jack or connecting a USB connector, the user just needs to bend the covering portion 35 relative to the engaging portion 39 via the flexible connecting portion 41, so that the protrusion 37 can be pulled out from the recess 55 for allowing that the user can plug an external connector of an external electronic device into the connecting terminal 25 via the opening 27. It should be mentioned that since the engaging portion is detachably engaged with the engaging structure 33, the waterproof cover 5 can utilize the design of the engaging direction D₁ of the engaging portion 39 being perpendicular to the upright direction D₂ of the opening 27, to effectively prevent the waterproof cover 5 from accidental falling off from the lower casing 9 during the bending process. Furthermore, if the user wants to detach the waterproof cover 5 from the lower casing 9 completely, the user can further pull the engaging portion 39 along the engaging direction D₁ to eject the hook end P₁ from the guide slot 45 of the engaging structure 33. As a result, the engagement of the engaging portion 39 and the engaging structure 33 is released.

Further detailed description for the protective casing 1 is provided as follows. As shown in FIG. 4, the protective casing 1 may further include a positioning unit 61 disposed in the second accommodating space S₂ and electrically connected to the circuit board 23. In practical applications, the positioning unit 61 is preferably a Global Positioning System (GPS). The positioning unit 61 can be used to assist the electronic device 19 in positioning itself and facilitate more accurate positioning.

As shown in FIG. 1, there is at least one hole 63 formed on the upper casing 11 for specific purposes (e.g. light emitting hole, button hole, etc.), and the upper casing 11 may include at least one waterproof member (e.g. waterproof film, waterproof glue, or any other appropriate transparent or at least semi-transparent film) covering the hole 63, so as to prevent water from entering the protective casing 1 via the hole 63. The waterproof member is not shown in the figure. Furthermore, there is at least one hole 65 formed on the lower casing 9 for specific purposes (e.g. speaker hole, microphone hole, etc.), and the lower casing 9 may also include at least one same or different waterproof member covering the hole 65, so as to prevent water from entering the protective casing 1 via the hole 65. Moreover, the upper casing 11 may include a second sealing member 67 disposed on an inner side of the upper casing 11, as shown in FIG. 6. The second sealing member 67 is exemplified by an O-ring in the present embodiment. When the protective casing 1 is in the closed state shown in FIG. 1, the second sealing member 67 can prevent water from entering the protective casing 1 via the gap between the upper casing 11 and the lower casing 9.

As shown in FIG. 6, the upper casing 11 further includes a transparent sheet 69 (e.g. PET film). When the electronic device 19 is accommodated in the first accommodating space S₁ and the protective casing 1 is in the closed state (as shown in FIG. 1), a touch panel 71 (as shown in FIG. 5) of the electronic device 19 abuts against the transparent sheet 69. Accordingly, the user may perform tactile operation to the touch panel 71.

Compared with the prior art, the present invention utilizes the engaging portion formed on the waterproof cover and the corresponding engaging structure formed at the side of the opening of the protective casing to be detachably engaged with each other, so as to fix the waterproof cover to the protective casing. Accordingly, it will not only save screws for fixing, but also simplify the related assembly and disassembly processes.

Those skilled in the art will readily observe that numerous modifications and alterations of the device and method may be made while retaining the teachings of the invention.

What is claimed is:

1. A waterproof cover implemented in a protective casing for an electronic device, an opening being formed on the protective casing at a position corresponding to a connecting terminal of a circuit board inside the protective casing, an engaging structure being formed on the protective casing at a side of the opening, and the waterproof cover comprising:
a covering portion having a protrusion for plugging into the opening when the covering portion covers the opening;
an engaging portion for detachably engaging with the engaging structure; and
a flexible connecting portion connecting the covering portion and the engaging portion for making the covering portion bendable relative to the engaging portion.

2. The waterproof cover of claim 1, wherein an engaging direction of the engaging portion and the engaging structure is substantially perpendicular to an upright direction of the opening.

3. The waterproof cover of claim 1, further comprising a sealing member disposed on an outer surface of the protrusion for forming a waterproof sealing between the covering portion and the inner surface of the opening.

4. The waterproof cover of claim 1, wherein the engaging portion has a hook member, the engaging structure has a corresponding guide slot formed therein, and a hook end of the hook member fastens an edge of the engaging structure after the hook member passes through the guide slot for fixing the engaging portion to the engaging structure.

5. The waterproof cover of claim 4, wherein the hook end is substantially T-shaped.

6. The waterproof cover of claim 4, wherein at least one chamfer is formed at the hook end of the hook member.

7. The waterproof cover of claim 4, wherein the hook end has a hole formed therein.

8. A protective casing for an electronic device comprising:
a main casing comprising:
a circuit board disposed therein and having a connecting terminal, an opening formed on the main casing at a position corresponding to the connecting terminal; and
an engaging structure formed at a side of the opening; and
at least one waterproof cover disposed on the main casing, the waterproof cover comprising:
a covering portion having a protrusion for plugging into the opening when the covering portion covers the opening;
an engaging portion for detachably engaging the engaging structure; and
a flexible connecting portion connecting the covering portion and the engaging portion for making the covering portion bendable relative to the engaging portion.

9. The protective casing of claim 8, wherein an engaging direction of the engaging portion and the engaging structure is substantially perpendicular to an upright direction of the opening.

10. The protective casing of claim 8, wherein a recess is formed above the opening for containing the waterproof cover when the covering portion covers the opening.

11. The protective casing of claim 8, wherein the waterproof cover further comprises a sealing member disposed on an outer side of the protrusion for forming a waterproof sealing between the covering portion and the inner surface of the opening.

12. The protective casing of claim 8, wherein the engaging portion has a hook member, the engaging structure has a corresponding guide slot formed therein, and a hook end of the hook member fastens an edge of the engaging structure after the hook member passes through the guide slot for fixing the engaging portion to the engaging structure.

13. The protective casing of claim 12, wherein the hook end is substantially T-shaped.

14. The protective casing of claim 12, wherein at least one chamfer is formed at the hook end of the hook member.

15. The protective casing of claim 12, wherein the hook end has a hole formed therein.

16. The protective casing of claim 8, wherein the flexible connecting portion comprises a plurality of groove structures.

17. The protective casing of claim 8, wherein the main casing comprises:
a lower casing; and
an upper casing cooperating with the lower casing to form a first accommodating space therebetween;
wherein the opening is selectively formed on one of the lowercasing or the upper casing.

18. The protective casing of claim 17, wherein the main casing further comprises a hinge assembly for pivotally connecting the upper casing and the lower casing.

19. The protective casing of claim 17, wherein the upper casing comprises a transparent sheet, and a display surface of the electronic device abuts against the transparent sheet when the electronic device is accommodated in the first accommodating space.

20. The protective casing of claim 17, wherein the upper casing comprises two fastener members pivotally connected to opposite sides of the upper casing, the lower casing comprises two fastener structures formed on opposite sides of the lower casing, and the two fastener members are detachably fastened with the two fastener structures respectively.

21. The protective casing of claim 17, wherein the lower casing comprises a partition member, the first accommodating space is above the partition member, and a second accommodating space is between the partition member and a bottom of the lower casing.

22. The protective casing of claim 21, further comprising a power supply unit disposed in the second accommodating space, the power supply unit is electrically connected to the circuit board, and when the electronic device is accommodated in the first accommodating space, a connector of the electronic device is electrically connected to a pin of the circuit board, such that the power supply unit supplies power to the electronic device.

23. The protective casing of claim 21, further comprising a positioning unit disposed in the second accommodating space and electrically connected to the circuit board.

24. The protective casing of claim 17, wherein at least one hole is formed on the upper casing, and the upper casing comprises at least one waterproof member disposed within the at least one hole respectively.

25. The protective casing of claim 17, wherein the upper casing comprises a sealing member disposed on an inner side of the upper casing.
